(19) United States
(12) Patent Application Publication
(10) Pub. No.: US 2024/0261727 A1
(43) Pub. Date: Aug. 8, 2024

(54) A PROCESS AND PLANT FOR CARBON EXTRACTION

(71) Applicant: Barrington IP Holdings Pty Ltd, Somerville Victoria (AU)

(72) Inventors: Garth Barrington DAVEY, Somerville, Victoria (AU); Venkata Vijay Kumar MADDALI, Clyde North, Victoria (AU)

(21) Appl. No.: 18/569,993

(22) PCT Filed: Jun. 14, 2022
(86) PCT No.: PCT/AU2022/050583

§ 371 Date: Dec. 13, 2023

(30) Foreign Application Priority Data
Jun. 14, 2021 (AU) 2021901775

(51) Int. Cl. B01D 53/62; B01D 53/24; B01D 53/60

(52) U.S. Cl. CPC B01D 53/62; B01D 53/24; B01D 53/60; B01D 2257/302; B01D 2257/404; B01D 2257/504; B01D 2258/0283

(57) ABSTRACT

Processes and plants are disclosed for separating carbon dioxide from a flue gas stream, for providing a source of atomic carbon by disassociating carbon dioxide and for generating electrical power from by-products of producing atomic carbon. In relation to separating carbon dioxide from a flue gas stream, the disclosed process includes energising a gas stream containing carbon dioxide to produce a disassociated stream by disassociating the carbon dioxide into atomic carbon and atomic oxygen using an energising apparatus. The process further includes separating the atomic carbon and the atomic oxygen into a carbon stream containing an atomic carbon phase and an oxygen stream containing an atomic oxygen phase using a high temperature cyclone apparatus.

### FILED OF THE PRESENT INVENTION

An embodiment of the present invention relates to a process and plant for separating carbon dioxide from a flue gas stream. Another embodiment of the present invention relates to a process and plant for disassociating atomic carbon from carbon dioxide to provide a source of carbon. Another embodiment of the present invention relates to a process and plant for the production of a carbonous solid material from atomic carbon.

### BACKGROUND OF THE PRESENT INVENTION

The two main industrial approaches for removing carbon dioxide from flue gas streams of coal or gas fired power stations involves the use of either chemical absorbents or physical adsorbents. Chemical absorbents can be regenerated using low temperature heat so they can be reused repeatedly. Physical adsorbents can be regenerated using pressure swing. The voluminous nature of flue gas streams usually favours the use of chemical absorbents.

In both cases, once the carbon dioxide has been desorbed it is then handled in a manner to prevent it from being release into the environment. This normally means the carbon dioxide is sequestered in geological formations of permanent storage.

It is an aim to provide an alternative to the existing processes.

### SUMMARY OF THE PRESENT INVENTION

Process for Separating CO₂ (and Other Acid Gases) from a Flue Gas Stream

An embodiment of the present invention relates to a process for separating acid gas(es) containing carbon dioxide from a flue gas stream, wherein the process includes:
(i) supplying a flue gas stream into a first cyclone apparatus;
(ii) separating the acid gases from lighter gases of the flue gas stream in the first cyclone by means of a density differences; and
(iii) discharging the first and second streams from the first cyclone apparatus, in which the first stream is rich in carbon dioxide and lean in nitrogen gas, and the second stream is rich in nitrogen gas and lean in carbon dioxide.

The first stream may be rich in acid gases and the second stream lean in the acid gases.

The acid gas(es) of the flue gas stream may include any one or a combination of the carbon dioxide (carbonic acid), carbon monoxide, oxides of sulphur (SOₓ) including sulphur dioxide, and oxides of nitrogen (NOₓ) including nitrogen oxide and nitrous oxide.

The lighter gases of the flue gas stream may consist of non-acid gases, including nitrogen, oxygen, and water vapour. The lighter gases may also include unburnt fuel including methane.

The process may include adding an intermediate gas species to the flue gas stream having a density that is less than a density of the acid gases and greater than a density of the lighter gases. It will be appreciated that the density of the gases of the flue gas stream may vary relative to each other depending on temperature, but generally speaking the density comparison is at a temperature approximately equal to the flue gas temperature, which may be after recuperative heat transfer from the flue gas stream. For instance, the temperature of the flue gas stream may be at temperature of greater than 100° C. and suitably approximately 140° C. which is the outlet temperature of flue gases from a boiler of the power station.

The purpose of the intermediate gas species is to provide a buffering gas species between the acid gas(es) and the lighter gas(es) to assist in separation of the acid gas(es) and the lighter gas(es). That is, the first gas stream may be more likely to include the acid gases and some of the intermediate gas with little or none of the lighter gases. Whereas when the process does not include adding the intermediate gas to the flue gas, the first stream may include a higher portion of the lighter gases.

In one example, the intermediate gas may be inert gas. For example, the intermediate gas may be a noble gas such as argon.

The process may include venting the second stream to atmosphere.

If the process includes adding the intermediate gas to the flue gas stream, and the intermediate gas is inert, the second stream may be vented to the atmosphere without separating the intermediate gas from the second stream. In the event that the intermediate gas can contribute to greenhouse effects, is toxic, or reactive, the process may include separating the intermediate gas from the second stream before venting the second stream to atmosphere.

The step of the operating the first cyclone apparatus may include controlling the swirl speed of the first cyclone apparatus and, in turn, an efficiency at which the acid gas(es) is/are separated from the lighter gas(es). Controlling the swirl speed may include controlling the speed of the flue gas entering the cyclone apparatus. For example, the speed of the flue gas may be at speed of approximately 15 to 40 m/sec, and suitably the range of the 20 to 35 m/sec, and even more suitably a speed in the range of 20 to 30 m/sec, and ideally a speed of approximately 25 m/sec. When the flue gas has an entering speed of approximately 25 m/sec the first cyclone separator may have a diameter in the range of 0.2 to 0.6 m, and suitably a diameter in the range 0.3 to 0.5 m.

The first stream may be discharged from the lower portion of the first cyclone apparatus and the second stream may be discharged from an upper portion of the first cyclone apparatus.

The first stream may be stored, geo-sequestered or treated further in downstream processes to provide a high purity carbon dioxide stream as desired.

In an example where the first stream includes carbon dioxide and at least one of SOₓ and NOₓ, the process may have a further separating step including:
(iv) supplying a first stream into a second cyclone apparatus;
(v) separating the at least one of SOₓ and NOₓ from carbon dioxide in the first stream by means of a density difference in the second cyclone apparatus; and
(vi) discharging from the second cyclone apparatus a third stream that is rich in carbon dioxide and lean in the at least one of SOₓ and NOₓ, and a gaseous fourth stream rich in at least one of SOₓ and NOₓ.

The third stream being less dense than the fourth stream will be discharged from an upper region of the second cyclone apparatus.

The process may include controlling a swirling speed in the second cyclone apparatus. For example, the process may include controlling the speed of the first gas stream entering the second cyclone apparatus and in turn, control the swirl speed in the second cyclone apparatus.

The process may also include a condensing step in which the at least one of SOₓ, and NOₓ if present, is condensed from the first stream and/or the third stream. A bypass may be provided so that all or part of the first stream can bypass the second cyclone separator and be fed to the condensing step.

The condensing step may be carried out irrespective of whether the further separating step is carried out. The condensing step may be carried out on the first stream. The condensing step may be carried out on the third stream being discharged from the second cyclone apparatus.

The condensing step may include passing the third stream though an indirect heat exchanger in which third stream is conveyed through a first side of a heat exchanger and the coolant is conveyed through a second side of the heat exchanger, and the at least one of SOₓ and NOₓ, is condensed into a liquid phase while carbon dioxide remains in a gas phase in the first side of the heat exchanger.

The first side of the heat exchanger may be arranged as a third cyclone apparatus in which SOₓ, and NOₓ if present, will have a tendency to move toward an (outer) wall of the third cyclone apparatus and carbon dioxide gas will have a tendency to move toward an inner region of the third cyclone separation apparatus.

A fifth stream including purified carbon dioxide gas may be discharged from the condensing step, and a sixth stream including liquified SOₓ, and NOₓ if present, may be discharged from the condensing step.

The second side of the heat exchanger may be arranged as a cooling jacket on the fourth cyclone separator and the coolant may be conveyed through the cooling jacket.

The coolant may be argon.

The process may include controlling the swirling speed in the third cyclone apparatus. Controlling the swirl speed may be carried out by controlling the speed at which the third gas stream enters the third cyclone separator. Similarly, the process may include controlling the speed of the first gas stream entering the second cyclone apparatus and in turn, controlling the swirl speed in the second cyclone separator.

In the event that the third stream includes the intermediate gas, which may be a noble gas, such as argon, the fourth stream may include the intermediate gas.

Plant for Separating CO₂ from a Flue Gas Stream

An embodiment of the present invention relates to a plant for separating acid gases including carbon dioxide from a flue gas stream, wherein the plant includes a first cyclone apparatus having an inlet that supplies a flue gas stream into the first cyclone apparatus so the flue gas swirls in the cyclone and therein causes the acid gases to separate from lighter gases of the flue gas stream by means of a density difference; wherein the first cyclone apparatus has an first outlet that discharges a first stream rich in carbon dioxide and lean in nitrogen, and second outlet that discharges the lighter gases.

The plant may have an intermediate gas source that supplies the intermediate gas into the flue gas stream, in which the intermediate gas has a density that is less than a density of the acid gases and greater than a density of the lighter gases.

The plant may have a first controller that controls the speed of the flue gas entering the first cyclone apparatus. Controlling the speed of the flue gas entering the first cyclone can be used to change the content composition of the first and second streams.

The first outlet may be arranged to discharge the first stream from a lower region of the portion of the first cyclone apparatus and the second outlet may be arranged to discharge the second stream from an upper portion of the first cyclone apparatus.

The plant may have a second cyclone separator having an inlet that supplies the first stream into the second cyclone apparatus, in which the first stream swirls in the second cyclone apparatus and therein causes the SOₓ, and NOₓ if present in the first stream, to separate from carbon dioxide by means of a density difference; wherein the second cyclone apparatus has an third outlet that discharges a third stream that is rich in carbon dioxide and lean in nitrogen, and fourth outlet that discharges a fourth stream that is rich in at least one of SOₓ and NOₓ.

The plant may include a condenser in which the at least one of SOₓ and NOₓ is condensed from the first stream and/or the third stream. A bypass may be provided so that all or part of the first stream can bypass the second cyclone separator and be fed to the condenser.

The condenser may include an indirect heat exchanger in which the third stream is conveyed through a first side of the heat exchanger and a coolant is conveyed through a second side of the heat exchanger, and the at least one of at least one of SOₓ and NOₓ, is condensed into a liquid phase whilst carbon dioxide remains in a gas phase in the first side of the heat exchanger.

The first side of the heat exchanger may be arranged as a fourth cyclone apparatus in which SOₓ, and NOₓ if present, will have a tendency to move toward an (outer) interface wall of the fourth cyclone apparatus and the carbon dioxide will have a tendency to move toward an inner region of the fourth cyclone separation apparatus.

At least part of the interface wall of the condenser may be maintained at an operating temperature −30° C. by the coolant. When the third stream contains SOₓ and is free of NOₓ, the SOₓ content of the condenser can be condensed in the condenser.

The condenser may have a fifth outlet that discharges a fifth stream including purified carbon dioxide, and a sixth outlet that discharges a liquified SOₓ, and NOₓ if present.

The second side of the heat exchanger may be arranged as a cooling jacket on the fourth cyclone and the coolant may be conveyed through the cooling jacket.

The plant described herein may include any one or a combination of the features of the process descried herein. Similarly, the process may include any one or a combination of the plant described herein.

Process of Preparing an Atomic Carbon Feed Stream from Carbon Dioxide

An embodiment of the present invention relates to a process of preparing an atomic carbon feed stream from carbon dioxide, the process includes the step of:
energising a gas stream containing carbon dioxide to dissociate the carbon dioxide into atomic carbon and atomic oxygen using an energising apparatus; and
separating atomic carbon and atomic oxygen into a carbon stream containing an atomic carbon phase and an oxygen stream including an atomic oxygen phase using a high temperature cyclone apparatus.

The process may further include converting the atomic carbon phase of the carbon stream into a carbon lattice structure.

The carbon lattice structure can be a 2D structure. Examples of 2D carbon structures include graphite oxide, graphite, graphene and graphene oxide. The 2D structures may be arranged into sheets, platelets, or tubular structures such as carbon nanotubes.

The gas stream may include an inert gas having a density between a density of the carbon phase stream and a density of the oxygen phase stream.

The carbon phase stream and the oxygen phase stream may include the inert gas.

The inert gas may be a noble gas such as either one or a mixture of helium, argon or neon. The purpose of the inert gas is to help buffer the carbon phase stream and the oxygen phase stream so that the carbon phase stream is free of atomic oxygen, and the oxygen phase stream is substantially free of atomic carbon.

The energising step may not have 100% efficiency, in fact it is expected that the disassociation may in the range of 80 to 95% efficient, and suitably approximately 90% efficient. In this instance, the process may include a step of separating a carbon dioxide stream from the disassociated stream. In this instance, the separating step may also produce a stream containing undissociated carbon dioxide.

The energising step may include heating the gas stream with electromagnetic radiation, suitably microwave radiation. For example, the energising apparatus may be a microwave plasma apparatus.

The energising step may include heating the gas stream to an elevated temperature of at least 1,980° C., and a suitably to a temperature of approximately 2,000° C. At these elevated temperatures, the atoms of carbon dioxide dissociate with the bonds between the carbon and oxygen atoms break to form atomic carbon and atomic oxygen.

The energising step may be carried out continuously, in which the gas stream, which is rich in carbon dioxide, is continuously fed into the energising apparatus. A disassociated stream containing atomic species of carbon and oxygen may be discharged continuously from the energising apparatus.

It is possible that the gas stream may be fed into the energising apparatus in a batch or discontinuous manner, and the disassociated stream may be discharged from the energising apparatus in a batch or discontinuous manner, respectively.

The disassociated stream may be fed directly into the high temperature cyclone apparatus to maintain the carbon and oxygen in their atomic forms.

The process may include controlling the temperature of the high temperature cyclone by feeding a first heat transfer medium to an outer jacket about the high temperature cyclone. In one example, the first heat transfer medium may transfer additional heat to the high temperature cyclone. In this instance, the objective is to prevent the carbon stream from cooling below the disassociation temperature.

In another example, the heat transfer medium may cool the high temperature cyclone.

The high temperature cyclone may have a high temperature resistant lining, such as hafnium oxide, ceramic, pyrolytic graphite or a geopolymer material.

The converting step may include forming a carbon lattice structure on a substrate, the substrate suitably including silicon dioxide.

The converting step may include controlling the temperature in which the converting step occurs. The formation of the carbon lattice structure from atomic carbon is a highly exothermic reaction, and controlling the temperature may include maintaining the temperature in which the converting step occurs in a range from to facilitate the carbon lattice. For example in the temperature range of the 1300 to 1650° C., and suitably in the range of the 1400 to 1500° C.

Controlling the temperature in which the converting step occurs may including transferring at least part of all of a heat of formation of the carbon lattice to a second heat transfer medium. Controlling the temperature in which the converting step occurs may also include transferring sensible heat to the second heat transfer medium. The second heat transfer medium may be argon gas.

The converting step may be carried out in a chamber and controlling the temperature of the converting step may include controlling the temperature inside the chamber.

The converting step may include depositing at least part of the atomic carbon phase onto a substrate that seeds growth of the carbon lattice structure. For example, the substrate may be silicon dioxide.

The process may include using heat energy of the second heat transfer medium to generate electrical power. For instance, heat energy and pressure of the second heat transfer medium may be used to drive a gas turbine, which in turn drives an electrical generator.

The electrical power generated may be used to power the energising apparatus.

The process may include using heat energy of the second heat transfer medium to heat a working gas, in which heat and pressure energy of the working gas is used to drive a gas turbine, which in turn drives the electrical generator. The working gas may be air and the second heat transfer medium may be argon.

Plant for Preparing an Atomic Carbon Feed Stream from Carbon Dioxide

An embodiment of the present invention relates to a plant for preparing an atomic carbon feed stream from carbon dioxide, the plant includes:
an energising apparatus for energising a gas stream containing carbon dioxide to dissociate the carbon dioxide into atomic carbon and atomic oxygen; and
a high temperature cyclone apparatus for separating atomic carbon and atomic oxygen into a carbon stream containing an atomic carbon phase and an oxygen stream including an atomic oxygen phase.
a chamber for converting the atomic carbon phase of the carbon stream into a carbon lattice structure

The energising apparatus may heat the gas stream with electromagnetic radiation, suitably microwave radiation. For example, the energising apparatus may be a microwave plasma apparatus.

The energising apparatus may heat the gas stream to an elevated temperature of at least 1,980° C., and a suitably to a temperature of approximately 2,000° C. At these elevated temperatures, the atoms of carbon dioxide dissociate with the bonds between the carbon and oxygen atoms breaking to form atomic carbon and atomic oxygen.

The energising apparatus may have an feed inlet that supplies the gas stream include carbon dioxide and a noble gas into a microwave plasma, and an discharge outlet that discharges a dissociated stream of atomic carbon and atomic oxygen. The outlet of the energising apparatus may be flow connected to a cyclone inlet that feds atomic carbon into the high temperature cyclone.

The high temperature cyclone apparatus may have a first outlet in a lower region for discharging a first stream containing atomic carbon, and a second outlet in upper region for discharging a second stream containing atomic oxygen.

The high temperature cyclone may have heat transfer device that is supplied a first heat transfer medium, and a controller for controlling the temperature of the high temperature cyclone by controlling the flowrate of a first heat transfer medium through the heat transfer device. The heat transfer device may be jacket about the high temperature cyclone.

In one example, the first heat transfer medium may transfer additional heat to the high temperature cyclone. In this instance, the objective is to prevent the carbon stream from cooling below the disassociation temperature. In another example, the heat transfer medium may cool the high temperature cyclone.

The high temperature cyclone may have a high temperature resistant lining, such as hafnium oxide, ceramic, a geopolymer material, or a refractory material.

The high temperature cyclone may have a diameter in the range of the 0.200 to 0.500 m, a suitably a diameter in the range of 0.250 to 0.450 m, and even more suitably a diameter in the range of 0.300 to 0.400 m.

The chamber in which the carbon lattice grows may include a substrate, suitably including silicon dioxide on which the carbon lattice structure is formed.

The chamber may include a heat controller that controls the temperature inside the chamber. The formation of the carbon lattice structure from atomic carbon is a highly exothermic reaction, and controlling the temperature of the chamber may include maintaining the temperature of the chamber in a range to facilitate growth of the carbon lattice. The temperature in the chamber may be controlled, for example, to a temperature in the range of 1300 to 1650° C., and suitably in the range of the 1400 to 1500° C.

The chamber may have a cooling device that receives a second heat transfer medium, and the cooling device is operable to transfer at least part of all of a heat of formation of the carbon lattice to a second heat transfer medium. The cooling device may also be operable to transfer sensible heat to the second heat transfer medium. The second heat transfer medium may be argon gas.

The plant may include a power generator and a gas turbine in which heat energy of the second heat transfer medium is used to generate electrical power. For instance, the heat energy and pressure of the second heat transfer medium drives a gas turbine which in turn drives an electrical generator.

The electrical power generated may be used to power the energising apparatus.

The plant may also include a heat exchanger device that transfers heat energy from the second heat transfer medium to a working gas, and the working gas can then be used to drive a gas turbine, which in turn drives the electrical generator.

### A Method of Powering the Energising Apparatus/Microwave Apparatus

Another embodiment of the present invention relates to a method of powering an energising apparatus, the method including the steps of:
energising a gas stream containing carbon dioxide to disassociate atomic carbon and atomic oxygen using an energising apparatus;
generating electrical power from heat energy available from the heat of formation of a carbon lattice structure from the atomic carbon; and
powering the energising apparatus using the electrical power.

The heat energy available for generating electrical power may include at least part of, and suitably all of, a heat of formation of the carbon lattice structure. The heat energy available for generating electrical power may include sensible heat released in converting the atomic carbon to a carbon lattice structure.

The heat energy available for generating the electrical power may include a heat of formation from converting atomic oxygen to an oxygen gas.

In the situation in which the gas stream includes a second gas species, suitably a noble gas such as argon, the heat energy available for generating electrical power may include sensible heat from second gas species that has been energised by the energising apparatus.

In the situation in which the carbon dioxide is obtained from a flue gas stream of a fired power station, the heat available for generating electrical energy may include sensible heat from the flue gas stream.

The heat energy available for generating electrical power may be transferred to a high temperature gas stream. For example, in the range of the 1,200 to 1,400° C.

The high temperature gas stream may be used to directly drive a gas turbine, in which the gas stream is expanded and cooled. The gas turbine in turn drives an electrical power generator.

The high temperature gas stream may also be used to heat a working gas stream, such as nitrogen or air, to a working temperature and pressure, and the working gas stream is used to drive a gas turbine which in turn drives am electrical power generator.

The energy required to the dissociate atomic carbon from carbon dioxide in the energising apparatus is approximately 2.382 MW/858 Kg of CO₂ and the potential heat energy from the heat of formation of the carbon lattice structure is 3.875 MW/233.45 Kg of carbon nanotubes.

### A Plant for Powering the Energising Apparatus/Microwave Apparatus

Another embodiment of the present invention relates to a plant for powering an energising apparatus that disassociates carbon dioxide, the plant includes:
an energising apparatus that energises a gas stream containing carbon dioxide which to disassociate atomic carbon and atomic oxygen using;
a generator that generates electrical power from heat energy that includes at least part of the heat of formation of a carbon lattice structure from the atomic carbon; and
a distributor that powers the energising apparatus by supplying the electrical power generated by the generator to the energising apparatus.

The plant for powering the energising apparatus may include any one of a combination of the features of (i) plant for separating acid gases including carbon dioxide from a flue gas stream, and (ii) the plant for making a carbon lattice structure from carbon dioxide. For example, the plant includes a chamber where the atomic carbon is converted to a carbon lattice structure, and in which the chamber may include a cooling device that receives a second heat transfer medium, and the cooling device being operable to transferring at least part of all of a heat of formation of the carbon lattice to a second heat transfer medium. The cooling device may also be operable to transfer sensible heat to the second heat transfer medium.

The plant may be located at fired power station and the flue gas stream may be from a boiler of the power station. The fired power station may be gas fired power station or coal fired power station.

### BRIEF DESCRIPTION OF THE DRAWINGS

Embodiments of the invention will now be described with reference to the accompanying figures which can be summarised as follows.

FIG. 1 is a block diagram of a process and plant of separating acid gases from a flue gas stream.

FIG. 2 is a block diagram of a process and plant of making a carbon lattice from carbon dioxide. The carbon dioxide may be separated from the flue gas stream shown in FIG. 1.

FIG. 3 is a schematic diagram which includes the items: a first speed controller, first cyclone separator, water condenser and a second speed controller shown in FIG. 1.

FIG. 4 is a schematic diagram including the items of FIGS. 1 and 2.

FIGS. 5A and 5B are oblique and side elevation view respectively of a cyclone separator suitable for separating carbon dioxide from flue gas and for separating atomic carbon from atomic oxygen.

FIG. 6 is an enlarged view of the gas turbines and the power generator which is driven by a bull gear shown in FIG. 1.

FIG. 7 is an enlarged view of the gas turbine and power generator and heat exchangers that form part of the cooler and the heat change network shown in FIG. 2.

FIG. 8 is a block diagram of a method of powering the energising apparatus that disassociates carbon dioxide.

FIG. 9 is an example energy balance in which the plant, process and method is incorporated into, or operates in conjunction with a coal fired power station.

### DETAILED DESCRIPTION

Preferred embodiments will now be described in the following text which includes reference numerals that correspond to features illustrated in the accompanying Figures. However to maintain clarity of the Figures, not all of the reference numerals are included in each Figure.

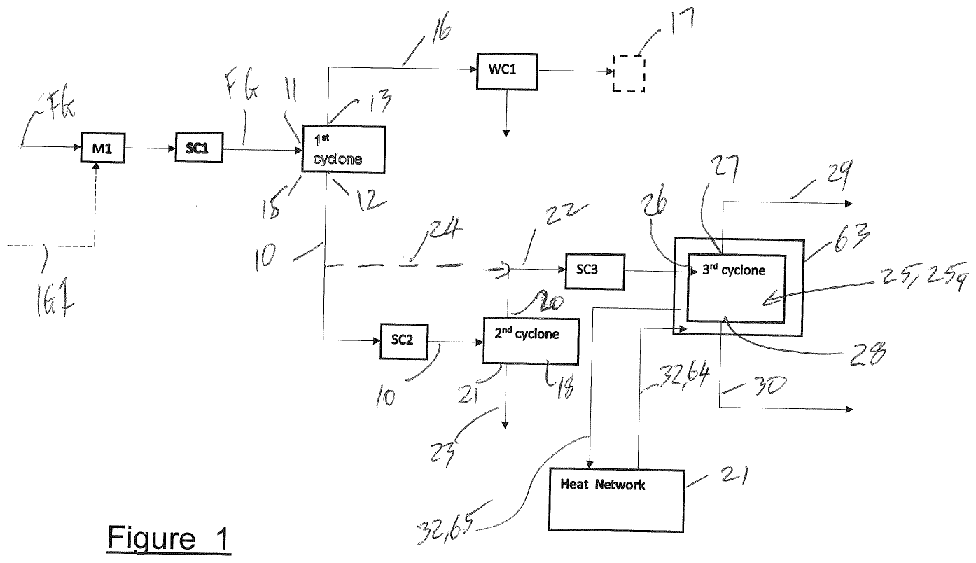

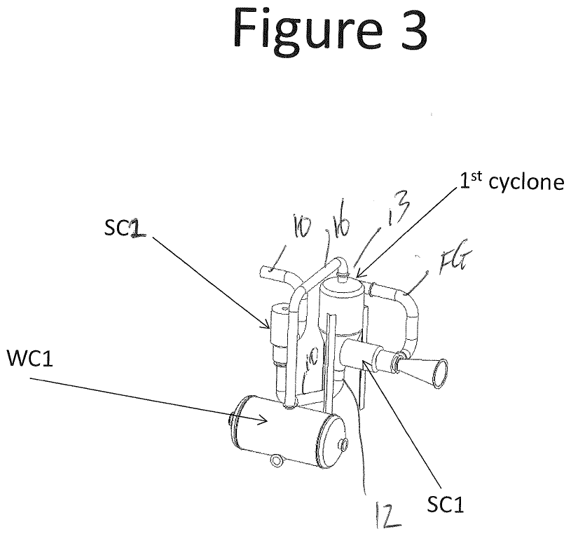

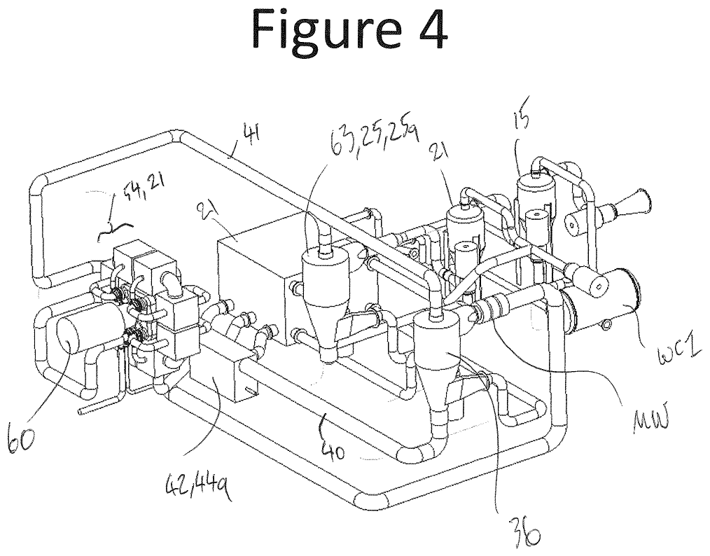

Carbon dioxide is at a concentration of approximately 410 ppm in the atmosphere at present and is increasing largely due to flue gases of fired power station. Carbon dioxide makes up from 7 to 15% by volume of most flue gases. FIG. 1 is a block diagram of a process and plant for separating carbon dioxide from a flue gas stream, and FIGS. 3 and 4 illustrate some of the equipment items in FIG. 1 in more details.

The process and plant in FIG. 1 are based in part on the premise that acid gases including carbon dioxide, SOₓ and NOₓ can be separated from the other types of gas in the flue gas stream FG using centrifugal forces in one or more cyclone separator(s) on account of density differences between the gas species.

Specifically, at pressures of 1 atm and at 140° C., water vapour has a density of 0.529 kg/m³, nitrogen is a density of 0.81 kg/m³, oxygen has a density of 0.93 kg/m³, carbon dioxide has a density of 1.28 kg/m³, and sulphur dioxide has a density of 1.87 kg/m³.

With reference to FIG. 1, the process and plant includes mixing a first intermediate gas stream IG1, suitably an inert gas, and even more suitably a noble gas such as argon with the flue gas stream FG in mixer M1. Argon is a particularly suitable because it has a density greater than nitrogen and oxygen, but less than the density of carbon dioxide, sulphur dioxide and other acid gases including NOₓ. Argon has a density of 1.16 kg/m³ at 1 atm and 140° C. and therefore can act as a buffer to help separate the acid gases in from the lighter gases the flue gas stream FG using centrifugal forces.

After mixing with argon, the flue gas stream FG is fed into a first cyclone apparatus 15 having a known maximum diameter at a known inlet flow rate or speed through a first inlet 11, which in turn controls the swirl speed the first cyclone apparatus 15. The flow rate through the first inlet 11 is controlled by a first speed controller SC1. The first speed controller SC1 may be any suitable device including a valve or throttle in the event that the speed needs to be reduced, or a centrifugal fan or compressor for increasing the flow rate and thus the speed of the flue gas stream FG fed into the first inlet 11.

Ideally the first cyclone apparatus 15 has a fixed geometry which enables an inlet speed of 25 m/s to effectively separate the flue gas stream into higher and lower density streams. The higher density stream, notionally referred to as a first stream 10, is discharged from a first outlet 12 at a lower region of the first cyclone apparatus 15. The first stream 10 is rich in acid gases, and lean in non-acid gases such as water vapour, oxygen and nitrogen. If an intermediate gas stream IG1, such as argon is mixed with the feed flue gas stream FG, the first stream 10 may also include a portion of argon. The lower density stream, notionally referred to as the second stream 16, is discharged from a second outlet 13 at an upper region of the first cyclone apparatus 15. The second stream 16 is rich in water vapour, oxygen, nitrogen and argon if added to the flue gas stream FG. The argon acts as a buffer in the sense that it provides a medium between the first and second streams 10 and 16 to reduce the amount of water vapour, oxygen and nitrogen in the first stream 10.

The second stream 16 may then be further processed to condense water therefrom in water condenser WC1. If argon gas is present in the second stream 16, the argon gas may be stripped from the second stream in intermediate gas separator 17 prior to venting to atmosphere.

The first stream 10 is then further treated by means of either one or combination of a condensation step and/or a centrifugal separation step to separate carbon dioxide for SOₓ, and if present NOₓ. SOₓ will be largely present in the form of sulphur dioxide and will condense at minus 10° C., and NOₓ will condense at approximately minus 88° C.

FIGS. 1 and 3 illustrate the first stream 10 being fed into a second cyclone apparatus 18 via second speed controller SC2. The second speed controller SC2 is arranged to control the flow rate and thus the speed of the first stream 10 entering into the second cyclone apparatus 18 via a second inlet 19 and in turn, the swirl speed and the efficiency of centrifugal forces for separating carbon dioxide from SOₓ, and NOₓ if present. The second cyclone apparatus 18 will separate the first stream 10 into a higher density stream and a lower density stream.

The lower density stream of the second cyclone apparatus 18, notionally referred to as a third stream 22 is discharged from a third outlet 20 located at an upper region of the second cyclone apparatus 18. Specifically, the third stream 22 will be richer in carbon dioxide than the first stream 10 and may have trace amounts of SOₓ and, if present NOₓ.

The higher density stream of the second cyclone apparatus 18, notionally referred to as the fourth stream 23 is discharged from the fourth outlet 21 located at a lower region of the second cyclone apparatus 18. Specifically, the fourth stream 21 will comprise SOₓ and, if present NOₓ.

The third stream 22 is then fed to a condenser 25 which includes a third cyclone separator 25a and a cooling jacket 63 that extends about the third cyclone separator 25a. In essence, the third cyclone apparatus 25a provides one side of heat exchanger and the cooling jacket 63 provides a second side of the heat exchanger which provides indirect cooling to the inside of the third cyclone apparatus 25a. A recirculating refrigerant or coolant 32 is circulated to the cooling jacket 63 via coolant line 64 and return coolant line 65 to a heat exchange network 31.

The outer wall of the third cyclone apparatus 25a is chilled via the cooling fluid to a desired operating temperature, for example −10° C. to condense SOₓ. If required, a portion of the outer wall of the second cyclone apparatus 25a may be chilled further to −88° C. to condense NOₓ. The SOₓ and NOₓ components will condense as these species will be in contact with the outer wall, and be discharged from the third cyclone apparatus 25a as sixth stream 30 is a liquid phase via the sixth outlet.

A fifth stream 29 comprising high purity carbon dioxide, and if present argon, will be discharged via the fifth outlet 27 at an upper region of the third cyclone apparatus 25a.

The fifth stream 29 may then be handled as desired to prevent release of the carbon dioxide to the atmosphere.

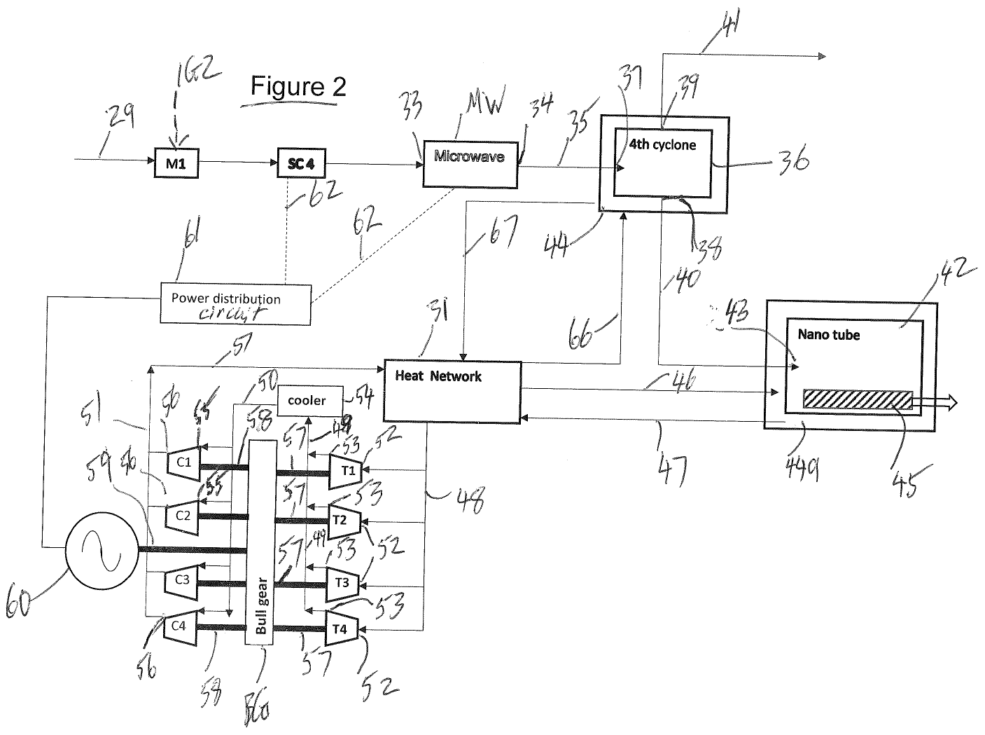

FIG. 2 is a block diagram of a process and plant for the making a carbon lattice structure from carbon dioxide. FIG. 4 illustrates the equipment items in FIGS. 1 and 2.

A stream of a high purity carbon dioxide, such as the fifth stream 29 from FIG. 1 is energised using a microwave apparatus MW. Prior to being supplied into the microwave apparatus MW, a second intermediate stream IG2 of argon may be mixed in mixer M2. The flow rate of the fifth stream 29 that is conveyed to a microwave MW inlet 33 and the flow rate of a seventh stream 35 that is discharged from a microwave outlet 34 are controlled by a fourth speed controller SC4. The fourth speed controller SC4 can in turn control the residence time of the carbon dioxide in the microwave apparatus MW.

The microwave apparatus MW and the fourth speed controller SC4 are operated to heat stream 29 to a temperature in excess of the disassociation temperature of carbon dioxide, which is approximately 1,980° C. Typically, temperatures inside the microwave apparatus MW will be in the order of 2000° C. At this temperature, the molecular bonds between the carbon and oxygen atoms will break, dissociating carbon dioxide into carbon atoms and oxygen atoms.

The process may include adding argon to the fifth stream 29 because argon has a density between the densities of atomic oxygen and atomic carbon at this elevated temperature. Argon can then act as a buffing gas species to assist in effectively separation of atomic carbon and atomic oxygen.

The process includes separating the atomic carbon and atomic oxygen in a high temperature cyclone separator 36. Specifically, the seventh stream 35 containing atomic carbon and atomic oxygen is fed directly into the high temperature cyclone 36 from the microwave apparatus MW. The fourth speed controller SC4 can be operated to control the entrance flow rate the seventh stream 35 and in turn the swirl speed inside the fourth speed controller SC4 to achieve effective separation of atomic carbon and atomic oxygen.

Argon is selected for the following reasons: 1) It has excellent thermal properties that allow it to couple energy into molecules. 2) Being a noble gas, it does not take part in the chemical process. 3) Argon has a density which is higher than oxygen but lower than carbon (amorphous). Due to the density difference, argon was expected to form a layer between the atomic carbon and atomic oxygen in the high temperature cyclone 36. Argon being an inert gas does not combine with either atomic carbon or atomic oxygen, and hence was expected to provide a clear separation zone between the atomic carbon and atomic oxygen. The carbon in the atomic carbon stream 40 is regarded as behaving as a solid material, whereas the oxygen in the atomic oxygen stream 41 is regarded as gaseous material, which in part explains why atomic carbon is more dense than atomic oxygen, whilst carbon has a lower atomic mass than oxygen. Atomic carbon having the highest density in the mix was expected to be collected on the wall of the high temperature cyclone 36 and slide down toward a bottom end outlet (particle outlet) of the high temperature cyclone 36, whereas the atomic oxygen being the lightest was expected to be collected near the axis of the high temperature cyclone 36. A layer of argon was expected to separate the atomic carbon and oxygen. Argon and oxygen are extracted through the top end outlet (vortex end outlet). The amorphous carbon collected on the wall is expected to slide down the cyclone wall.

An atomic carbon stream 40 of high purity atomic carbon, and entrained argon is discharged from the first high temperature outlet 38 located at, or toward, a bottom region of the high temperature cyclone 36. Similarly, an atomic oxygen stream 41 of high purity atomic oxygen and entrained argon is discharged from the second high temperature outlet 39 locate at, or toward, an upper region of the high temperature cyclone 36.

The temperature inside the high temperature cyclone 36 is maintained to be above the bond breaking temperature of CO₂, to prevent the recombination of carbon and oxygen into CO₂. That is, the high temperature cyclone 36 will be operated at, or above, the dissociation temperature of carbon dioxide to maintain dissociation.

To maintain structural integrity of equipment items such as the high temperature cyclone 36 and associated pipelines, the inner surface of these items may be lined with hafnium oxide, ceramic, a geopolymer material, or a suitable refractory material to insulate the structure from the high temperature streams.

For example, the high temperature cyclone 36 can be constructed in titanium and coated with an ultra-high temperature ceramic material. In this case, the preferred ceramic material is Hafnium dioxide. The Hafnium dioxide (HfO₂) refractory coat provides the required thermal insulation and also increases the oxidation resistance. The HfO₂ coating is 100% dense; therefore a pinhole-free coating is applied on the inner walls of the high temperature cyclone 36. The HfO₂ coating can extend the service life of the equipment due to increased operating temperature capacity of the components. Hafnium dioxide (HfO₂) is preferred for two reasons: it has a low rate of oxidation at elevated temperatures (around 46 g/cm·sec at 1800° C.); and it has a high melting point (2810° C.).

In addition, the high temperature cyclone 36 can be fitted with a cooling device 44, such as a cooling jacket for controlling the temperature of the internal walls which are insulated from the high temperature of the atomic carbon stream 40. The cooling device 44 can be supplied with a recirculating coolant via lines 66 and 67 from a heat exchange network, which may include a HVAC unit.

The atomic carbon may accumulate on the walls of the high-temperature cyclone 36. Such accumulation is disadvantageous because it reduces the amount of atomic carbon which is available for downstream processing. It is believed that dissociation of the carbon dioxide into atomic carbon and atomic oxygen by microwave heating leaves the atomic carbon with an electrical charge. The accumulation of carbon on the side walls of the high-temperature cyclone is thought to be wholly or partly due to that charge. Therefore, the high-temperature cyclone 36 may have side walls that are electrically charged with a charge that is the same as the charge of the atomic carbon. For example, it is thought that the atomic carbon will have a positive charge after microwave heating and dissociation of carbon dioxide and, therefore, a positive charge is also applied to the walls in the high-temperature cyclone 36 to reduce accumulation of carbon.

The atomic carbon stream 40 is fed into a converter chamber via inlet 43 in which a carbon lattice structure, suitably in the form a carbon nanotube is progressively grown on a host substrate 45. The substrate 45 may be any suitable material such as a silicon dioxide substrate onto which carbon atoms or clusters can deposited. The first layer of carbon reacts with silicon dioxide of the substrate 45 to form silicon carbide which then acts as a catalyst that assists further growth of nanotubes.

In one example, not illustrated in the Figures, the chamber 42 may include a cylinder and piston arrangement that facilitates continuous growth of carbon nanotubes by the substrate being arranged on the piston and then receding as the grow of the nanotube progresses. This arrangement constantly exposes the open end of the growing nanotubes to the right temperature, which facilitates further growth. In any event, the substrate 45 and/or carbon nanotube may be retracted from the chamber 42 is the nanotube grows as depicted by the arrow in FIG. 2.

The chamber 42 has a cooling device 44a for controlling the temperature inside to chamber 42 to range that facilitates the formation of the carbon nanotubes. For instance, the cooling device 44a can maintain the chamber 42 at an operating temperature in the range of 600 to 1650° C., and suitably in the range of approximately 1150° C.

One of the main functions of the cooling device 44a is to transfer the heat of the formation of the carbon nanotube to a cooling fluid. The heat formation being in the range of −6.78 to −7.40 eV/atom where eV/atom=eV/mole. In other words, converting atomic carbon to a carbon nanotube is a highly exothermic reaction.

Ideally, the cooling device 44a surrounds at least part of the chamber 44 and cooling fluid, such as argon is passed through the cooling device 44a and circulated between the cooling device 44a and the heat exchanger network 31 via supply line 46 and return line 47. In view of the significant amount of the energy being released within the chamber 42, the high temperature heat energy being absorbed by the cooling fluid which can be used to the generate electrical power that can be used to power the microwave MW that disassociates the carbon dioxide of stream 29.

For instance, the high temperature cooling fluid in return line 47 can be used to perform work by directly driving a gas turbine and generate electrical power. However, in the preferred embodiment, the high temperature cooling fluid in line 47 is received by the heat exchange network 31 in which heat energy from the high temperature cooling fluid is transferred to a working fluid to provide a high temperature working fluid. The high temperature working fluid is conveyed from the net exchanger network and fed via line 48 to a gas turbines T1, T2, T3 and T4 where the working fluid expands, cools and provides work that is transmitted to a bull gear BG via turbine output drive 57. The bull gear in turn operates a power generator 60 via the generator link 59, shown in FIG. 2. Power from the power generator 60 is supplied to a power distribution circuit 61 and power lines 62 can then supply power the microwave MW and any other items within the plant, such as centrifugal compressors or fans of speed controllers SC1, SC2, SC3 and SC4. Power from the power generator may also be used to power equipment outside the plant outside of the plant, and the power generator may be any suitable generator, including AC or DC generators.

The working fluid is handled in closed loop circuit according to a Carnot circuit. Specifically, compressed working fluid from the compressor outlet 56 is supplied to the head exchange network via line 51 where the working fluid is heated to a high temperature. Line 48 supplies the high temperature working fluid to the turbine inlets 52 to drive the gas turbines T1, T2, T3 and T4. Line 49 conveys expanded working fluid to a cooler 54 to further reduce the temperature of the working fluid prior to re-pressurisation in compressors C1, C2, C3 and C4. The cooler 54 may be operated using any suitable cooling medium including a cooling fluid, ambient cooling water, ambient air. Line 50 supplies the cool working fluid to the compressor inlets 55. Each compressor C1, C2, C3 and C4 are operably connected to the bull gear BG via compressor drive links 58, shown in FIG. 2. Compressed working fluid is discharged by the compressor outlets 56 and are reheated in the head exchange neck network as described above.

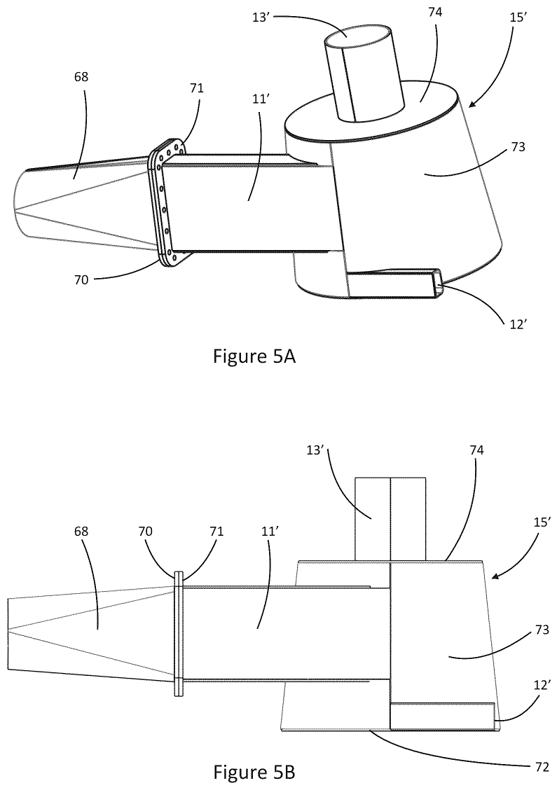

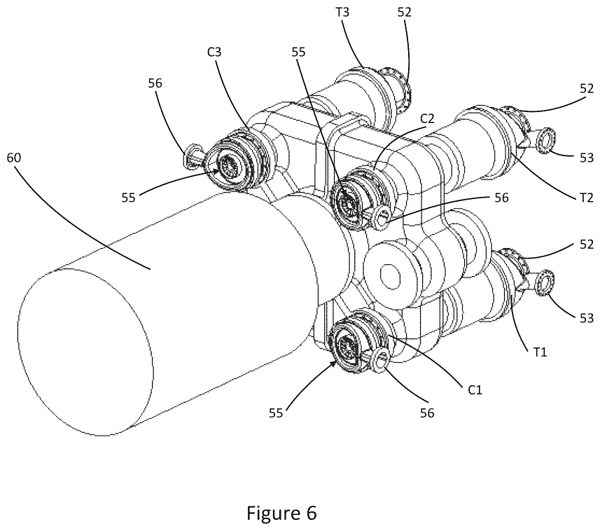

FIGS. 5 and 6 are an enlarged schematic view of power installation comprising the turbines T1, T2 and T3 arranged about the rear aspect of a housing that contains the bull gear BG, and the compressors C1, C2 and C3 arranged about a front aspect of the housing. Turbine T4 and compressor C4 cannot be seen in FIGS. 5 and 6 on account of the oblique respective illustrated. The power generator 60 is centrally located at the front of the housing. Compressor inlets and outlets 55 and 56, respectively, and a turbine inlet and outlets 52 and 53, respectively, can also be seen.

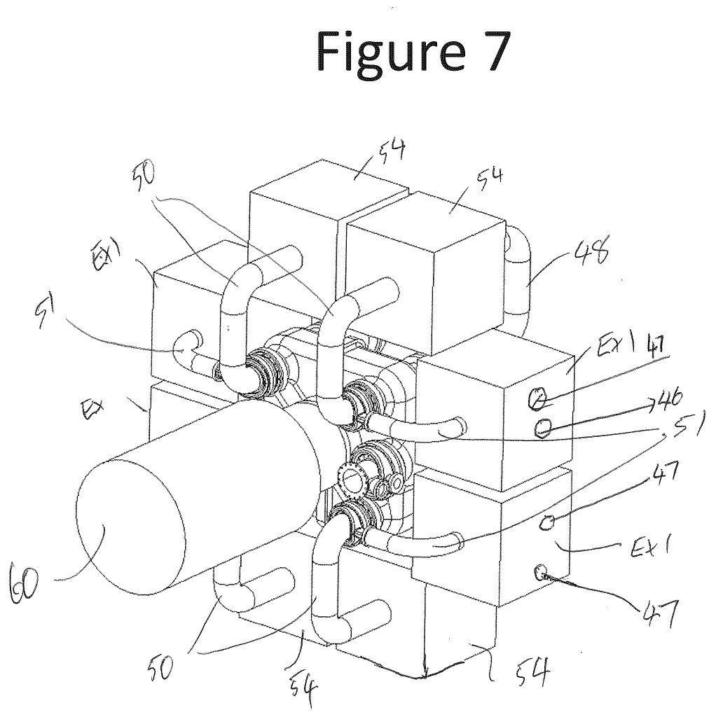

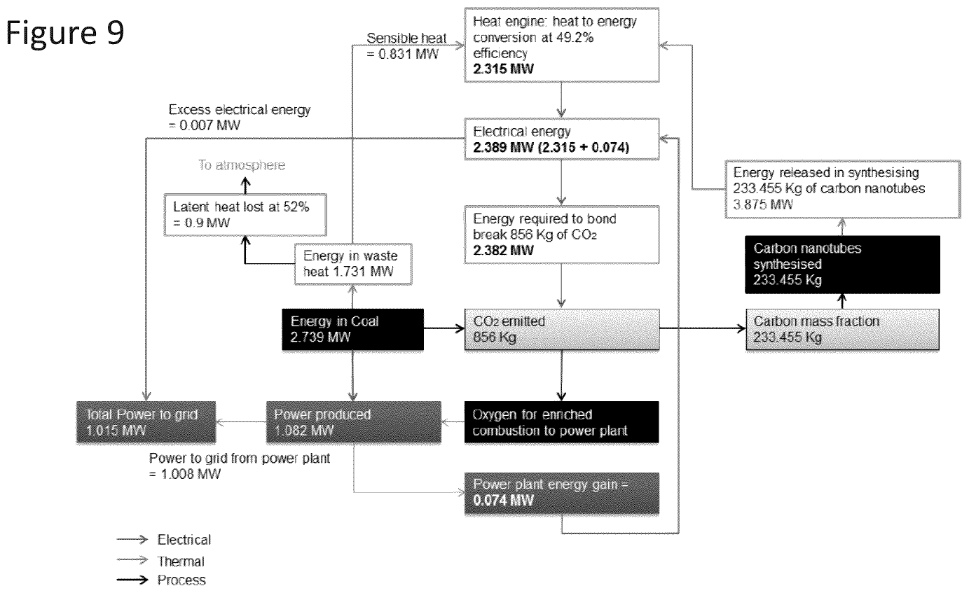

The heat network 31 and are cooler 54 are schematically represented as single blocks in FIG. 2. However, it will be appreciated that the heat network 31 and cooler 54 may be provided by multiple heat exchangers. FIG. 7 is an enlarged schematic of the power installation together with heat exchangers that form part of the heat network 31 and cooler 54 that handle the cooling fluid and the working fluid. Specifically, with reference to FIG. 7 the compressed working fluid line 51 conveys compressed working fluid high temperature heat exchangers EX1 of the heat network 31 in which high temperature heat from the cooling fluid supplied by the return line 47 from the chamber 42. Working fluid from the heat exchangers EX1 is supplied directly to the turbine inlet 52 via high temperature working fluid line 48, which is not shown in FIG. 7. The expanded working fluid line 49 extending from the turbine outlet 53 then conveys the working fluid to the dedicated cooling unit 54A. As can be seen in FIG. 9 each of the four gas turbines T1, T2, T3 and T4 has dedicated working fluid circuits, each comprising heat exchangers EX1 and a cooling units 54A. It will be appreciated that many variations and modifications may be made to the power installation illustrated in FIGS. 2, 7 and 8 depending on the temperature profiles and the equipment items chosen. For example, gas turbines T1, T2, T3 and T4 may be arranged in series with a one or more additional heating steps of the working fluid between the gas turbines. In addition, the individual gas turbines T1, T2, T3 and T4 may themselves be single stage turbines or a multi-stage gas turbines as desired.

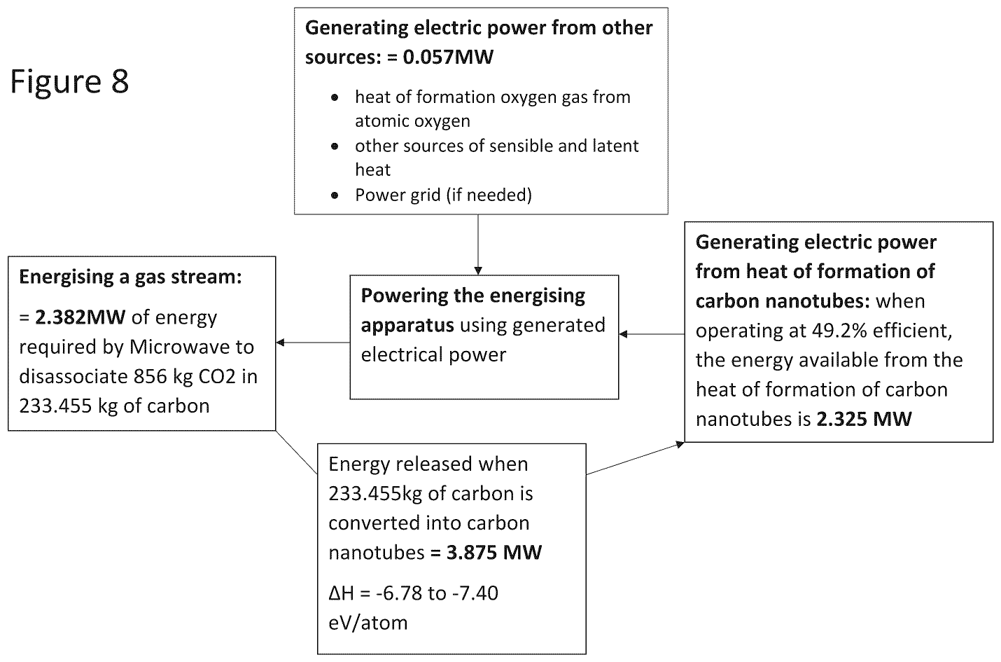

FIG. 8 is a block diagram of a method of powering the energising apparatus/microwave MW. The energy values in FIG. 8 are based on supplying 856 kg of carbon dioxide which is a notional or assumed amount of carbon dioxide in a flue gas FG of coal fire power station supplying 1 MW of power to the grid. The actual mass of carbon dioxide used is immaterial to this example, but it does provide energy levels. To dissociate carbon dioxide using a microwave plasma operating at approximately 2000° C., the microwave (MW) will require approximately a 2.382 MW of energy to dissociate 858 kg of carbon dioxide into 233.45 kilograms of carbon. The amount of energy released when 233.45 kg of carbon is converted into a lattice structure in the form of carbon nanotubes is at least 3.875 MW. The energy released on heat of formation of carbon nanotubes is approximately ΔH −7.4 eV/mole. By using a Carnot closed loop heat engine, approximately 49.2% of the heat energy can be converted into electrical energy. In other words, approximately 2.325 MW of power can be generated from the heat energy released on the formation of carbon nanotubes. That is, there is an energy shortfall of approximately 0.057 MW. However, this shortfall can be readily provided by utilising heat energy from other sources such as, but by no means limited to, the following: (i) Heat of formation of oxygen gas from atomic oxygen. Atomic oxygen is a by-product from the high temperature cyclone separator 36. (ii) Other sources of sensible heat, such as waste heat supplied to heat sink water at a coal-fired power plant. If required, additional power could be sourced from renewable energy sources such as solar power, wind power or from a power grid.

FIG. 9 is a block diagram of an energy balance is an example in which a coal-fired power plant supplies approximately 1 MW of power to the grid. Process streams are represented in black, thermal streams are represented in green and electrical power is represented in blue. The values in FIG. 9 represents the following:
(i) The total energy that could potentially be recovered from waste heat and the synthesis of carbon nanotubes is 4.706 MW.
(ii) The energy in waste heat on burning coal for power production is approximately 0.831 MW.
(iii) The CO₂ emissions are approximately 858 Kg/MW.
(iv) The amount of energy required to dissociate the CO₂ emissions, i.e. 858 kg is approximately 2.382 MW.
(v) The mass fraction of the carbon liberated by disassociating CO₂ is approximately 233.45 Kg.
(vi) 233.45 Kg of carbon nanotubes could be synthesised for every 1 MW of power produced by the power plant.
(vii) The amount of energy released in synthesising the carbon nanotubes is 3.875 MW, based on a heat of formation of approximately ΔH=−7.4 eV/mole.
(viii) On account of the efficiency of heat engines, in total, 2.315 MW of electrical power is generated from the 4.706 MW equivalent of thermal energy.
(ix) An additional 0.074 MW of energy is generated as a result of increased plant efficiency facilitated by oxygen enhanced combustion.
(x) In total, the energy recovered and available for CO₂ bond breaking is 2.389 MW which is marginally higher (0.007 MW) than that the energy required (2.382 MW) for the same.

This energy balance is based on a heat engine efficiency of 49.2%. In the event that the heat engine efficiency is 40%, 42.5%, or 60%, the total amount of energy that could be recovered from the heat energy of the formation of the carbon nanotube could be in the order of 1.956, 2.074, or 2.897 MW respectively. This energy balance is also based on the formation of the carbon nanotubes. The type of carbon lattice structure formed will have an impact on the amount of energy released.

Whilst a number of specific apparatus and method embodiments have been described, it should be appreciated that the apparatus and method may be embodied in other forms. For example, an alternative configuration first cyclone apparatus 15′ is shown in FIGS. 5A and 5B. The first cyclone apparatus has a hollow frusto-conical body 14 comprising a base plate 72 and a side wall 74 extending from the base plate 72 to a top plate 73. The top plate 73 is parallel to the base plate 72.

The angle of inclination of the side wall 73 to the base plate 72 is selected depending on the composition of feed gas supplied to the first cyclone apparatus 15′ because the angle of inclination affects the gas separation efficiency of the cyclone. The angle of inclination between the bottom plate 72 and the side wall 73 is in the range of 5 to 25°. Alternatively, the angle of inclination between the bottom plate 72 and the side wall 73 is in the range of 5 to 10°. In the first cyclone apparatus 15′, the angle of inclination is 8° between the bottom plate 72 and the side wall 73.

A first inlet 11′ joins the body 14 in a tangential orientation. This configuration directs gas flowing from the first inlet 11′ into the body 14 in a direction that is tangential to the side wall 73 at the end of the first inlet 11′. In this orientation, gas flowing through the inlet 11′ and into the body 14 establishes the cyclone swirl required for separation of the gas species. The inlet 11′ has a trapezoidal profile with an outer wall having the same angle of inclination as the side wall 74 relative to the base plate 72. The first inlet 11′ also has an inner wall, opposite to the outer wall, which is aligned parallel to a longitudinal axis of the body 14. The inlet 11′ includes a connecting flange 71 at an end of the inlet 11′ remote from the body 14. Upper outlet 13′ extends from the top plate 74 and comprises a cylindrical tube having its longitudinal axis aligned with the longitudinal axis of the body 14. A lower outlet 12′ extends from the body 14. The outlet 12′ is oriented tangentially with the side wall 74. The outlet 12′ is positioned below the level of the first inlet 11′ and is spaced from the first inlet 11′. In operation, a gas, comprising two or more gas species, is supplied to the cyclone separator 15 via the first inlet 11′ and the gas is separated by cyclone separation into lower density gas species which exit via the upper outlet 13′ as one gas stream and into higher density gas species which exit via the lower outlet 12′ as another gas stream.

An inlet adaptor 68 is fitted to the inlet 11′ to form a connection between the first inlet 11′ and a cylindrical pipe conveying gas. The profile of the inlet adaptor 68 changes from its inlet end remote from the inlet 11 to a flange 70 at an outlet end which is connectable with the flange 71 of the first inlet 11′. More specifically, the profile changes gradually from a circular profile to the same trapezoidal profile as the first inlet 11′.

This alternative configuration for cyclone apparatus 15 may also be adopted for the second and/or third cyclone apparatus 18 and 25a and may also be adopted for the high-temperature cyclone 36.

In the claims which follow, and in the preceding description, except where the context requires otherwise due to express language or necessary implication, the word “comprise” and variations such as “comprises” or “comprising” are used in an inclusive sense, i.e. to specify the presence of the stated features but not to preclude the presence or addition of further features in various embodiments of the apparatus and method as disclosed herein.

In the foregoing description of preferred embodiments, specific terminology has been resorted to for the sake of clarity. However, the invention is not intended to be limited to the specific terms so selected, and it is to be understood that each specific term includes all technical equivalents which operate in a similar manner to accomplish a similar technical purpose. Terms such as “front” and “rear”, “inner” and “outer”, “above”, “below”, “upper” and “lower” and the like are used as words of convenience to provide reference points and are not to be construed as limiting terms. The terms “vertical” and “horizontal” when used in reference to the humidification apparatus throughout the specification, including the claims, refer to orientations relative to the normal operating orientation.

Furthermore, invention has been described in connection with what are presently considered to be the most practical and preferred embodiments, it is to be understood that the invention is not to be limited to the disclosed embodiments, but on the contrary, is intended to cover various modifications and equivalent arrangements included within the spirit and scope of the invention. Also, the various embodiments described above may be implemented in conjunction with other embodiments, for example, aspects of one embodiment may be combined with aspects of another embodiment to realize yet other embodiments. Further, each independent feature or component of any given assembly may constitute an additional embodiment.

Reference Table

| first mixer | M1 |
|---|---|
| first speed controller | SC1 |
| flue gas stream | FG |
| first intermediate gas stream | IG1 |
| first stream | 10 |
| first inlet | 11 |
| first outlet | 12 |
| second outlet | 13 |
| first cyclone apparatus | 15 |
| second stream | 16 |
| water condenser | WC1 |
| intermediate gas separator | 17 |
| second speed controller | SC2 |
| second cyclone apparatus | 18 |
| second inlet | 19 |
| third outlet | 20 |
| fourth outlet | 21 |
| third stream | 22 |
| fourth stream | 23 |
| third speed controller | SC3 |
| bypass line | 24 |
| condenser/third cyclone apparatus | 25, 25a |
| third inlet | 26 |
| fifth outlet | 27 |
| sixth outlet | 28 |
| fifth stream | 29 |
| sixth stream | 30 |
| heat exchanger network | 31 |
| recirculating coolant | 32 |
| second intermediate stream | IG2 |
| second mixer | M2 |
| fourth speed controller | SC4 |
| energising apparatus/microwave | MW |
| microwave inlet | 33 |
| microwave outlet | 34 |
| seventh stream | 35 |
| high temperature cyclone | 36 |
| high temp cyclone inlet | 37 |
| first high temp cyclone outlet | 38 |
| second high temp cyclone outlet | 39 |
| atomic carbon stream | 40 |
| atomic oxygen stream | 41 |
| converting step/chamber | 42 |
| chamber inlet | 43 |
| cooling device | 44, 44a |
| substrate | 45 |
| supply line | 46 |
| return line | 47 |
| gas turbines | T1, T2, T3, T4 |
| high temp working fluid line | 48 |
| expanded working fluid line | 49 |
| cooled working fluid line | 50 |
| compressed working fluid line | 51 |
| turbine inlet | 52 |
| turbine outlet | 53 |
| cooler | 54 |
| compressors | C1, C2, C3, C4 |
| compressor inlet | 55 |
| compressor outlet | 56 |
| bull gear | BG |
| turbine output drive link | 57 |
| compressor drive link | 58 |
| generator link | 59 |
| power generator | 60 |
| power distributor circuit | 61 |
| power lines | 62 |
| high temperature heat exchangers | EX1 |
| cooling jacket | 63 |
| coolant line | 64, 66 |
| return line | 65, 67 |
| inlet | 11′ |
| first outlet | 12′ |
| second outlet | 13′ |
| inlet adaptor | 68 |
| flange | 70 |
| flange | 71 |
| base plate | 72 |
| top plate | 73 |
| side wall | 74 |

1-52. (canceled)

53. A process for separating acid gas(es) containing carbon dioxide from a flue gas stream, wherein the process includes:
supplying a flue gas stream into a first cyclone apparatus;
separating the acid gases from lighter gases of the flue gas stream in the first cyclone by means of density differences; and
discharging first and second streams from the first cyclone apparatus, in which the first stream is rich in carbon dioxide and lean in nitrogen gas, and the second stream is rich in nitrogen gas and lean in carbon dioxide.

54-57. (canceled)

58. The process defined in claim 53, wherein the process includes adding an intermediate gas species to the flue gas stream having a density that is less than a density of the acid gases and that is greater than a density of the lighter gases.

59. The process defined in claim 58, wherein the process includes venting the second stream to atmosphere.

60. The process defined in claim 58, wherein the process includes separating the intermediate gas from the second stream before venting the second stream to atmosphere.

61. The process defined in claim 53, further comprising a step of the operating first cyclone apparatus, which includes controlling a swirl speed of the first cyclone apparatus and, in turn, an efficiency at which the acid gas(es) is/are separated from the lighter gas(es).

62. The process defined in claim 61, wherein controlling the swirl speed includes controlling the speed of the flue gas entering the cyclone apparatus.

63. The process defined in claim 61, wherein controlling the swirl speed includes controlling the speed of the flue gas entering the cyclone apparatus to be at a speed in a range of 15 to 40 m/sec.

64-66. (canceled)

67. The process defined in claim 53, wherein the first cyclone separator has a diameter in a range of 0.2 to 0.6 m.

68. (canceled)

69. The process defined in claim 53, wherein the first stream is discharged from a lower portion of the first cyclone apparatus and the second stream is discharged from an upper portion of the first cyclone apparatus.

70. (canceled)

71. The process defined in claim 53, wherein the process includes a condensing step in which the at least one of SOₓ, and NOₓ, if present, is condensed from the first stream.

72. The process defined in claim 53, wherein, when the first stream includes carbon dioxide and at least one of SOₓ and NOₓ, the process has a further separating step including:
supplying the first stream into a second cyclone apparatus;
separating the at least one of SOₓ and NOₓ from carbon dioxide in the first stream by means of a density difference in the second cyclone apparatus; and
discharging from the second cyclone apparatus a third stream that is rich in carbon dioxide and lean in the at least one of SOₓ and NOₓ, and a gaseous fourth stream rich in at least one of SOₓ and NOₓ.

73. (canceled)

74. The process defined in claim 72, wherein the process includes controlling a swirling speed in the second cyclone apparatus.

75. The process defined in claim 74, wherein the process includes controlling the speed of the first gas stream entering the second cyclone apparatus and, in turn, controlling the swirl speed in the second cyclone apparatus.

76. The process defined in claim 72, wherein the process includes a condensing step in which the at least one of SOₓ, and NOₓ if present, is condensed from the third stream.

77. The process defined in claim 76, wherein a bypass is provided so that all or part of the first stream can bypass the second cyclone separator and be fed to the condensing step.

78. (canceled)

79. The process defined in claim 76, wherein the condensing step includes passing the third stream though an indirect heat exchanger in which the third stream is conveyed through a first side of a heat exchanger and a coolant is conveyed through a second side of the heat exchanger and the at least one of SOₓ and NOₓ is condensed into a liquid phase while carbon dioxide remains in a gas phase in the first side of the heat exchanger.

80. The process defined in claim 79, wherein the first side of the heat exchanger is arranged as a third cyclone apparatus in which SOₓ, and NOₓ if present, will have a tendency to move toward an (outer) wall of the third cyclone apparatus and carbon dioxide gas will have a tendency to move toward an inner region of the third cyclone separation apparatus.

81. The process defined in claim 80, wherein the second side of the heat exchanger is arranged as a cooling jacket on a fourth cyclone separator and the coolant is conveyed through the cooling jacket.

82. (canceled)

83. The process defined in claim 80, wherein the process includes controlling a swirling speed in the third cyclone apparatus.

84. The process defined in claim 83, wherein the process includes controlling the speed of the third gas stream entering the third cyclone apparatus and, in turn, controlling the swirl speed in the third cyclone apparatus.

85-116. (canceled)
